(19) United States
(12) Patent Application Publication
(10) Pub. No.: US 2026/0255084 A1
(43) Pub. Date: Aug. 27, 2026

(54) IMAGE SENSING DEVICE, IMAGING SYSTEM INCLUDING IMAGE SENSING DEVICE, AND METHOD OF OPERATING IMAGING SYSTEM

(71) Applicant: SK hynix Inc., Icheon-si (KR)

(72) Inventor: Jae Hyung JANG, Icheon-si (KR)

(21) Appl. No.: 19/268,895

(22) Filed: Jul. 14, 2025

(30) Foreign Application Priority Data
Feb. 26, 2025 (KR) 10-2025-0024713

(51) Int. Cl. H04N 25/773; G01S 7/481; G01S 7/4861; G01S 7/4865; G01S 17/894; H04N 25/78; H10F 39/00

(52) U.S. Cl. CPC H04N 25/773; G01S 7/4816; G01S 7/4861; G01S 7/4865; G01S 17/894; H04N 25/78; H10F 39/8023

(57) ABSTRACT

An image sensing device is provided to comprise: pixels supported by a substrate, wherein the pixels includes a first pixel including: a first sub pixel including a first pixel area, and a portion of a second non-pixel area; second sub pixels, each including a second pixel area, another portion of the second non-pixel area, and a first non-pixel area; photoelectric conversion elements respectively placed in the first and second sub pixels and configured to detect a photon reflected from a target object and generate a pixel signal corresponding to the detected photon; a grid structure including first and second grids placed in the first and second non-pixel areas, respectively, wherein the substrate includes a first recess in the first non-pixel area and the substrate includes a second recess in the second non-pixel area, and a depth of the first recess is greater than a depth of the second recess.

### CROSS-REFERENCE TO RELATED APPLICATION(S)

This patent document claims priority to Korean Patent Application No. 10-2025-0024713, filed Feb. 26, 2025, the disclosure of which is incorporated herein for all purposes by this reference.

### TECHNICAL FIELD

Embodiments of the disclosed technology relate to an image sensing device, an imaging system including the image sensing device, and a method of operating the imaging system.

### BACKGROUND

Time of flight (TOF) technology, which has been in the spotlight recently, emits light in the form of a pulse from a light source placed in or near a sensor and receives the reflected light and measures the time between emission and reception to extract distance based on the law of constancy of the velocity of light. In order to measure TOF precisely, reaction must occur as soon as light reaches a light receiving element, so a highly sensitive photoelectric conversion device is required. To this end, research on a single-photon avalanche diode (SPAD) that may be manufactured using CMOS process technology has been widely conducted.

### SUMMARY

Various implementations of the disclosed technology provide an image sensing device, an imaging system, and a method of operating the imaging system that are capable of applying an SPAD for high illumination or short distances.

Some implementations of the disclosed technology provide an image sensing device, an imaging system, and a method of operating the imaging system with an improved dynamic range.

Some implementations of the disclosed technology provide an image sensing device, an imaging system, and a method of operating the imaging system with an improved power consumption by reducing exposure time and operation time.

Some implementations of the disclosed technology provide an image sensing device, an imaging system, and a method of operating the imaging system with an improved efficiency of a light source.

In one aspect, an image sensing device is provided to comprise: a substrate; and a plurality of pixels supported by the substrate, wherein the plurality of pixels includes a first pixel that includes: a first sub pixel included in a pixel of the plurality of pixels and including a first pixel area, and a portion of a second non-pixel area adjacent to the first pixel area; a plurality of second sub pixels disposed around the first sub pixel, each of the plurality of second sub pixels including a second pixel area, another portion of the second non-pixel area adjacent to the second pixel area, and a first non-pixel area between the second pixel area and a second pixel adjacent to the first pixel; photoelectric conversion elements respectively placed in the first sub pixel and the plurality of second sub pixels and configured to detect a photon reflected from a target object and generate a pixel signal corresponding to the detected photon; a grid structure disposed above the substrate and including a first grid placed in the first non-pixel area and the second non-pixel area, and a second grid placed in the second pixel area, and wherein the substrate includes a first recess in the first non-pixel area and the substrate includes a second recess in the second non-pixel area, and a depth of the first recess is greater than a depth of the second recess.

In another aspect, an imaging system is provided to comprise: an image sensing device including: a pixel array including a plurality of pixels, each including a first sub pixel configured to generate a first pulse signal and a plurality of second sub pixels positioned around the first sub pixel and configured to generate a second pulse signal; a first readout circuit configured to generate and store first pixel data based on the first pulse signal generated from the first sub pixel; and a second readout circuit configured to generate and store second pixel data based on the second pulse signal generated from the plurality of second sub pixels; and an image sensing processor configured to process the first pixel data and perform a summation processing on the second pixel data.

In another aspect, a method of operating an imaging system is provided. The method comprises: generating a first pulse signal by a first photoelectric conversion element of a first sub pixel included in a pixel of the imaging system; generating a second pulse signal by second photoelectric conversion elements of a plurality of second sub pixels disposed around the first sub pixel; generating, by a first readout circuit in the imaging system, first pixel data based on the first pulse signal by a first readout circuit; generating, by a second readout circuit in the imaging system, second pixel data based on the second pulse signal; processing, by an image signal processor (ISP) in the imaging system, the first pixel data; and performing, by the ISP in the imaging system, a summation processing on the second pixel data.

Details of other embodiments are included in the detailed description and the drawings.

According to embodiments, the first sub pixel and the second sub pixel are operated in a distinguishing manner, and optical charges applied to the first sub pixel may leak to the second sub pixel. Thus, this is applicable for high illumination or short distances.

According to embodiments, the first sub pixel and the second sub pixel are operated in a distinguishing manner, and optical charges applied to the first sub pixel may leak to the second sub pixel, and the ISP performs summation processing on pixel data generated from the first sub pixel and pixel data generated from the second sub pixel, thereby improving dynamic range.

According to embodiments, the first sub pixel and the second sub pixel are operated in a distinguishing manner, and optical charges applied to the first sub pixel may leak to the second sub pixel, and the ISP performs summation processing on pixel data generated from the first sub pixel and pixel data generated from the second sub pixel, thereby reducing exposure time and operation time and thus improving power consumption.

According to embodiments, the first sub pixel and the second sub pixel are operated in a distinguishing manner, and optical charges that may be saturated in the first sub pixel may leak to the second sub pixel for use, thereby improving the efficiency of the light source.

However, effects that may be obtained from the disclosed technology will not be limited to only the above described effects. In addition, other effects which are not described herein will become apparent to those skilled in the art from the following description.

### BRIEF DESCRIPTION OF THE DRAWINGS

FIG. 1 is a block diagram illustrating an imaging system based on some implementations of the disclosed technology.

FIG. 2 is a plan view of a pixel array based on some implementations of the disclosed technology.

FIG. 3 is an enlarged plan view of area Q1 of FIG. 2.

FIG. 4 is a cross-sectional view taken along line A-A′ shown in FIG. 3.

FIG. 5 is a diagram illustrating a direct ToF method of a pixel.

FIG. 6 is a diagram illustrating an indirect ToF method of a pixel.

FIG. 7 is a diagram illustrating an imaging system based on some implementations of the disclosed technology.

FIG. 8 is a diagram illustrating modes of a single-photon avalanche diode based on some implementations of the disclosed technology.

FIG. 9 is a schematic diagram illustrating that some of the light incident to a first sub pixel leaks to a second sub pixel.

FIG. 10 is a diagram illustrating a conversion of a first pulse signal generated by a first sub pixel to first pixel data.

FIG. 11 is a diagram illustrating a conversion of a second pulse signal generated by second sub pixels to second pixel data.

FIG. 12 is a graph illustrating intensity code over light emission time of an imaging system according to a comparative example.

FIG. 13 is a graph illustrating intensity code over light emission time of an imaging system based on some implementations of the disclosed technology.

FIG. 14 is a flowchart illustrating a method of operating an imaging system based on some implementations of the disclosed technology.

FIG. 15 is a cross-sectional view of a pixel array based on some implementations of the disclosed technology.

FIG. 16 is a plan view of a pixel based on some implementations of the disclosed technology.

FIG. 17 is a plan view of a pixel based on some implementations of the disclosed technology.

FIG. 18 is a plan view of a pixel based on some implementations of the disclosed technology.

FIG. 19 is a plan view of a pixel based on some implementations of the disclosed technology.

FIG. 20 is a flowchart illustrating a method of operating an imaging system based on some implementations of the disclosed technology.

FIG. 21 is a cross-sectional view of a pixel array based on some implementations of the disclosed technology.

### DETAILED DESCRIPTION

Hereinafter, embodiments will be described with reference to the accompanying drawings.

The same reference numerals refer to same elements. In the drawings, the thicknesses, ratios, and sizes of the elements are exaggerated for effective description of the technical details. The term “and/or” includes one or more combinations that the associated elements may define.

It is to be understood that terms such as “including”, “having”, and the like are intended to indicate the existence of the features, numbers, steps, actions, elements, components, or combinations thereof disclosed in the specification, and are not intended to preclude the possibility that one or more other features, numbers, steps, actions, elements, components, or combinations thereof may exist or may be added.

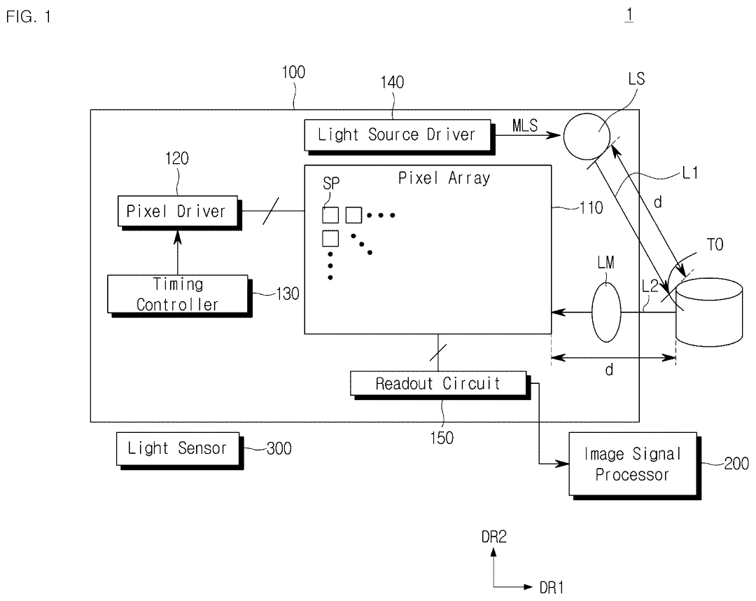

FIG. 1 is a block diagram illustrating an imaging system according to an embodiment.

Referring to FIG. 1, the imaging system 1 may refer to a device, such as a digital still camera for capturing still images, or a digital video camera for capturing videos. For example, the imaging system 1 may be implemented as a digital-single lens reflex camera (DSLR), a mirrorless camera, or a mobile phone (in particular, a smartphone), but is not limited thereto. The imaging system 1 has a concept that includes a device capable of capturing a subject and generating images by including a lens and an imaging device.

The imaging system 1 may include an image sensing device 100 and an image signal processor 200.

The image sensing device 100 may measure distance using the time-of-flight (TOF) principle. The image sensing device 100 may include a condensing pattern (ML), a pixel array 110, a pixel driver 120, a timing controller 130, a light source driver 140, and a readout circuit 150. The imaging system 1 according to an embodiment may further include a light sensor 300. The imaging system 1 may further include a light source (LS).

The light source (LS) may emit light to a target object (TO) in response to a clock signal (MLS) from the light source driver 140. The light source (LS) may be a laser diode (LD) emitting light in a particular wavelength band (for example, infrared or visible light), a light-emitting diode (LED), a near-infrared laser (NIR), a point light source, a monochromatic light source which is a combination of a white lamp and a monochromator, or a combination of other laser light sources (LSs). For example, the light source (LS) may emit infrared light having a wavelength of 800 nm to 1000 nm. Although FIG. 1 shows only one light source (LS) for convenience of description, a plurality of light sources (LSs) may be arranged near the condensing pattern (ML). In an embodiment, the light source (LS) is illustrated as a near-IR laser light source (vertical cavitiy surface emitting laser (VCSEL)) including a point light source, but the embodiment of the disclosed technology is not limited thereto.

The condensing pattern (ML) may collect light reflected from the target object (TO) and focus the light onto the pixels of the pixel array 110. The condensing pattern (ML) may include a focusing lens or other optical element with a glass or plastic surface. The condensing pattern (ML) may include one lens group of at least one lens. The condensing pattern (ML) may be a micro lens, but embodiments of the disclosed technology are not limited thereto.

The pixel array 110 may include a plurality of pixels (SPs) continuously arranged in a 2D matrix structure including columns and rows. For example, the pixel array 110 may include the plurality of pixels (SPs) continuously arranged in a first direction (DR1) and a second direction (DR2). Each pixel (SP) performs photoelectric conversion on second light (L2) (or incident light) received through the condensing pattern (ML) to generate and output a pixel signal which is an electrical signal corresponding to the second light (L2). Herein, the pixel signal may be a signal indicating information corresponding to the distance to the target object (TO) rather than a signal indicating a color of the target object (TO). Each of the plurality of pixels (SPs) may include a single-photon avalanche diode.

The pixel array 110 in which the plurality of pixels (SPs) are arranged may use a direct ToF method to detect the distance to the target object (TO). For reference, the direct ToF method is to calculate the distance to the target object (TO) by directly measuring the round trip time starting from the time point at which pulse light is emitted to the target object (TO) to the time point at which pulse light reflecting from the target object (TO) is incident and by computing the round trip time and the velocity of light. However, embodiments of the disclosed technology are not limited thereto, and the pixel array 110 in which the plurality of pixels (SPs) are arranged may use an indirect ToF method to detect the distance to the target object (TO).

The pixel driver 120 may drive the pixel array 110 based on the control of the timing controller 130. For example, the pixel driver 120 may generate a quenching control signal for controlling the quenching operation that reduces the reverse bias voltage applied to the pixel (SP) to the breakdown voltage or below. Thus the pixel driver 120 may control the turning on/turning off of the pixel (SP) based on the control of the timing controller 130.

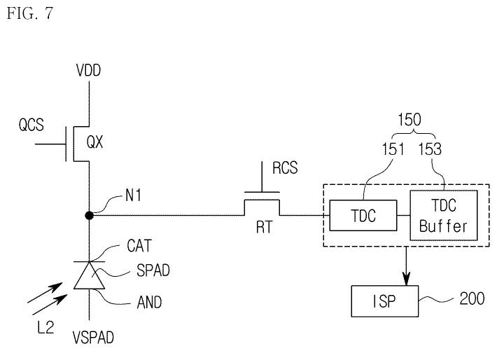

The readout circuit 150 may be placed on one side of the pixel array 110 and may calculate the time delay between a pulse signal (or pixel signal) output from each pixel (SP) and a reference pulse and may generate (see a time-to-digital (TDC) part 151 of the readout circuit 150 shown in FIG. 7) and store (see a TDC buffer (or TDC memory) 153 of the readout circuit 150 shown in FIG. 7) digital data (or pixel data) corresponding to the time delay. The readout circuit 150 may transmit the stored digital data to the image signal processor 200 based on the control of the timing controller 130.

The timing controller 130 may control the overal operation of the image sensing device 100. That is, the timing controller 130 may generate a timing signal for controlling the operation of the pixel driver 120 and the light source driver 140. In addition, the timing controller 130 may control activation or deactivation of the readout circuit 150, and may control the digital data stored in each readout circuit 150 to be transmitted to the image signal processor 200 either simultaneously or sequentially.

The light source driver 140 may generate a clock signal for driving the light source (LS) based on the control of the timing controller 130.

The image signal processor 200 (or ISP) may process digital data (or pixel data) input from the image sensing device 100, and may generate a depth image (in the form of a histogram) representing the distance to the target object (TO). Specifically, the image signal processor 200 may calculate the distance to the target object (TO) for each pixel on the basis of the time delay represented by the digital data received from the readout circuit 150.

The image signal processor 200 may control the operation of the image sensing device 100. In particular, the image signal processor 200 may analyze the digital data input from the image sensing device 100 to determine the mode of the image sensing device 100, and may control the image sensing device 100 to operate in the determined mode.

The image signal processor 200 may perform image signal processing on the generated depth image to remove noise and improve image quality. The depth image output from the image signal processor 200 may be stored in an internal memory or an external memory of the imaging system 1 or a device equipped with the imaging system 1 at the request of a user or automatically, or may be displayed on a display. Alternatively, the depth image output from the image signal processor 200 may be used to control the operation of the imaging system 1 or the device equipped with the imaging system 1.

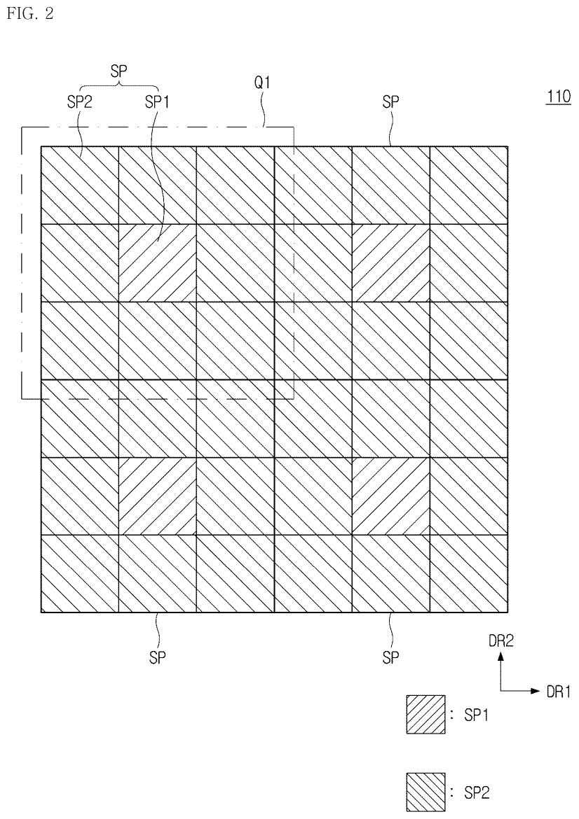

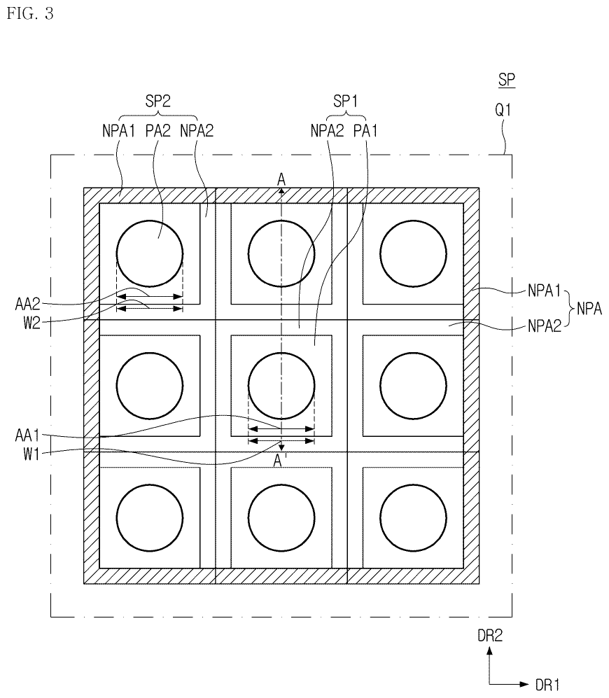

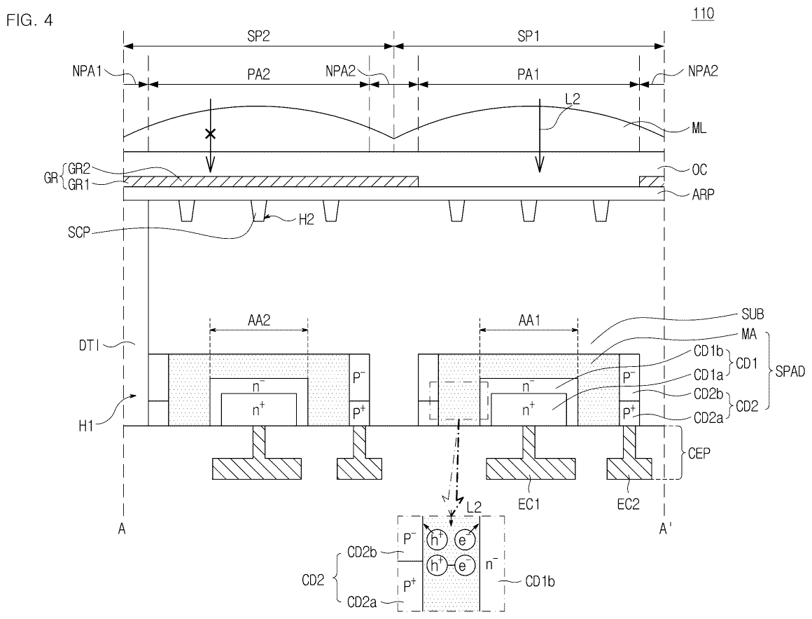

FIG. 2 is a plan view of a pixel array according to an embodiment. FIG. 2 illustrates a plurality of pixels, each including the first sub pixel (SP1) and the plurality of second sub-pixels SP2 disposed around the first sub-pixel (SP1). Although not shown in FIG. 3, the plurality of pixels is supported by a substrate (SUB as shown in FIG. 4).

Referring to FIG. 2, a pixel array 110 may include a plurality of pixels (SPs). The plurality of pixels (SPs) may include a first sub pixel (SP1), and a plurality of second sub pixels (SP2s) around the first sub pixel (SP1). For example, referring to FIG. 2, there may be one first sub pixel (SP1) and eight second sub pixels (SP2s) located in the vicinity of the first sub pixel (SP1). The number of the second sub pixels located in the vicinity of the first sub pixel (SP1) is not limited to eight and other implementations are also possible. In one pixel (SP), the number of second sub pixels (SP2s) may be greater than the number of first sub pixels (SP1s), and the second sub pixels (SP2s) may be arranged to surround the first sub pixel (SP1).

The arrangement of the first sub pixel (SP1) and the second sub pixel (SP2) in the pixel can be modified in various manners. The number of first sub pixels (SP1s) and second sub pixels (SP2s) of the pixel array 110 may vary in various embodiments. FIG. 2 shows an example in which one first sub pixel (SP1) and eight second sub pixels (SP2s) constitute one group pixel. However, in some embodiments, the first sub pixel (SP1) and the second sub pixel (SP2) may constitute one group pixel in various ways, for example, one first sub pixel (SP1) and one second sub pixel (SP2) constitute one group pixel.

In addition, FIG. 2 shows that the first sub pixel (SP1) is surrounded by the second sub pixels (SP2s), but the arrangement of the first sub pixel (SP1) and the second sub pixel (SP2) is not limited thereto. For example, the second sub pixels (SP2) may be disposed on sides of the first sub pixel (SP1) or disposed in proximity of the first sub pixel (SP1).

A detailed plan view of one pixel (SP) will be shown in FIG. 3.

FIG. 3 is an enlarged plan view of area Q1 of FIG. 2.

Referring to FIG. 3, the first sub pixel (SP1) may include a first pixel area (PA1), and a second non-pixel area (NPA2) near the first pixel area (PA1), and the second sub pixel (SP2) may include a second pixel area (PA2), a first non-pixel area (NPA1) near the second pixel area (PA2), and the second non-pixel area (NPA2) near the second pixel area (PA2). The first non-pixel area (NPA1) may correspond to a boundary between the pixels (SPs) in FIG. 2, and the second non-pixel area (NPA2) may correspond to a boundary between a first sub pixel (SP1) and a second sub pixel (SP2) adjacent to each other, and to a boundary between adjacent second sub pixels (SP2s), within one pixel (SP).

In an embodiment, the first pixel area (PA1) of the first sub pixel (SP1) may include a first active area (AA1), and the second pixel area (PA2) of the second sub pixel (SP2) may include a second active area (AA2).

The cross-sectional structure of each of the sub pixels (SP1 and SP2) will be described with reference to FIG. 4.

FIG. 4 is a cross-sectional view taken along line A-A′ shown in FIG. 3. FIG. 4 shows the cross-sectional structure of each of the sub pixels (SP1 and SP2), specifically, the cross-sectional structure of the first and second pixel areas (PA1 and PA2) and the non-pixel areas (NPA1 and NPA2).

Referring to FIG. 4, a pixel array 110 according to an embodiment may include a substrate (SUB), a circuit (CEP) disposed on a first surface of the substrate, photodetectors, e.g., single photon avalanche diodes (SPADs) in the substrate (SUB) and in the respective pixel areas (PA1 and PA2) on the circuit (CEP), a grid part (GR) disposed above a second surface of the substrate (SUB), a planarizing layer (OC) on the grid part (GR), and a condensing pattern (ML) on the planarizing layer (OC). In the example, the photodetector may be or include a single-photon avalanche diode (SPAD) and the condensing pattern (ML) may be or include a micro lens. However, other implementations are also possible.

The circuit (CEP) is placed at the bottom of the photodetector (SPAD), and may include transistors, a wiring layer, and an interlayer insulation layer. The transistors may include an analog quenching transistor and a readout transistor formed at the bottom of the photodetector (SPAD). For example, FIG. 4 illustrates that the circuit (CEP) includes a first electrode (EC1) electrically connected to a first semiconductor area (CD1), and a second electrode (EC2) electrically connected to a second semiconductor area (CD2). The first electrode (EC1) may be an electrode connected to an analog quenching transistor, which will be described later, or an electrode of an analog quenching transistor, and the second electrode (EC2) may be an electrode to which a diode voltage, which will be described later, (see VSPAD in FIG. 7) is applied, but embodiments of the disclosed technology are not limited thereto.

The photodetector (SPAD) may include the first semiconductor area (CD1), the second semiconductor area (CD2), and an intermediate area (MA) between the first semiconductor area (CD1) and the second semiconductor area (CD2).

The first semiconductor area (CD1) may be an n-type semiconductor area, and the second semiconductor area (CD2) may be a p-type semiconductor area. For example, p-type ions may include boron (B) ions, and n-type ions may include phosphorous (P) and/or arsenic (As) ions. For example, the first semiconductor area (CD1) may include a 1-1 semiconductor area (CD1a), which is an n+ type semiconductor area on the circuit (CEP), and a 1-2 semiconductor area (CD1b), which is an n− type semiconductor area on the 1-1 semiconductor area (CD1a). The second semiconductor area (CD2) may include a 2-1 semiconductor area (CD2a), which is a p+ type semiconductor area on the circuit (CEP), and a 2-2 semiconductor area (CD2b) which is a p− type semiconductor area on the 2-1 semiconductor area (CD2a).

For example, the 1-1 semiconductor area (CD1a) may have a higher doping concentration of n-type impurities than the 1-2 semiconductor area (CD1b), and the 2-1 semiconductor area (CD2a) may have a higher doping concentration of p-type impurities than the 2-2 semiconductor area (CD2b). However, embodiments of the disclosed technology are not limited thereto, and the first semiconductor area (CD1) and the second semiconductor area (CD2) may include only one n-type and one p-type semiconductor area.

In some embodiments, the relative positions of the 1-1 semiconductor area (CD1a) and the 1-2 semiconductor area (CD1b) may be varied. For example, while FIG. 4 illustrates the 1-2 semiconductor area (CD1b) disposed on the 1-1 semiconductor area (CD1a), in some implementations, the 1-1 semiconductor area (CD1a) may be disposed on the 1-2 semiconductor area (CD1b). Similarly, the relative position of the 2-1 semiconductor area (CD2a) and the 2-2 semiconductor area (CD2b) may be varied.

The intermediate area (MA) may be positioned between the first semiconductor area (CD1) and the second semiconductor area (CD2). The intermediate area (MA) may also be positioned at the top of the first semiconductor area (CD1). The mechanism of electrons (e−) and holes (h+) in the intermediate area (MA) will be discussed later.

FIG. 4 illustrates that the first semiconductor area (CD1) is positioned in the center and the second semiconductor area (CD2) is positioned in the periphery or one side of the first semiconductor area (CD1). However, embodiments of the disclosed technology are not limited thereto, and positions of the first and the second semiconductor area CD1 and CD2 may be changed.

The photodectors may be disposed in the substrate (SUB). The substrate (SUB) may include an n-type semiconductor area or a p-type semiconductor area. However, the impurity doping concentration of the substrate (SUB) may be lower than those of the first semiconductor area (CD1) and the second semiconductor area (CD2).

A first groove (H1) may be formed in the first non-pixel area (NPA1) of the substrate (SUB). The first groove (H1) may be formed by recessing the substrate (SUB) in the thickness direction. For example, the first groove (H1) may be recessed completely from the top to the bottom of the substrate (SUB) in the thickness direction. The first groove (H1) may be formed through a deep trench process. A separation part (e.g., deep trench isolation DTI structure) may be placed in the first groove (H1). In some implementation, the separation part is configured to separate the adjacent pixels from each other. An insulation material or a conductive material such as poly silicon may be placed in the separation part (e.g., DTI).

In some embodiments, a second groove (H2) may be formed in the pixel areas (PA1 and PA2). One or two second grooves (H2s) may be provided, or three or more second grooves (H2s) may be provided. The thickness (or depth) of the second groove (H2) may be smaller than the thickness (or depth) of the first groove (H1). A scatter pattern (SCP) may be positioned in the second groove (H2). The scatter pattern (SCP) may include at least one of the materials constituting an anti-reflection layer (ARP), which will be described later, but embodiments of the disclosed technology are not limited thereto.

The anti-reflection layer (ARP) may be placed on the substrate (SUB). The anti-reflection layer (ARP) enables second light (L2) incident from the outside not to be reflected but to be incident into the substrate (SUB). The anti-reflection layer (ARP) may include an insulation material. Examples of the insulation material may include HfO2, SiO2, and Al2O3, but embodiments of the disclosed technology are not limited thereto.

The grid part (GR) may be placed on the anti-reflection layer (ARP). The grid part (GR) may include metal that blocks second light (L2) incident from the outside, but embodiments of the disclosed technology are not limited thereto. The grid part (GR) may include tungsten (W), but embodiments of the disclosed technology are not limited thereto. The grid part (GR) may include a first grid (GR1) placed in the non-pixel areas (NPA1 and NPA2) and a second grid (GR2) placed in the second pixel area (PA2). The first grid (GR1) and the second grid (GR2) may be directly connected to each other. According to an embodiment, as the second grid (GR2) is placed in the second pixel area (PA2), second light (L2) may not be substantially incident directly to the substrate (SUB) in the second pixel area (PA2). However, as the second grid (GR2) is not placed in the first pixel area (PA1), second light (L2) may be incident to the substrate (SUB) in the first pixel area (PA1). In some embodiments, the second grid (GR2) may not be placed throughout the second pixel area (PA2), and the second grid (GR2) may be placed only in a partial area of the second pixel area (PA2).

The planarizing layer (OC) may be placed on the grid part (GR) and the anti-reflection layer (ARP). The planarizing layer (OC) may include an organic material, but embodiments of the disclosed technology are not limited thereto and the planarizing layer (OC) may include an inorganic material.

The condensing pattern (ML) may be positioned on the planarizing layer (OC). The condensing pattern (ML) may focus an externally incident light to be incident to the first pixel area (PA1). In some implementations, the condensing pattern (ML) may have the shape of a convex lens that curves upward, and may be formed of or include a material having a large difference in refractive index compared to the outside air. For example, the refractive index of the condensing pattern (ML) may range from about 1.5 to 1.6, but embodiments of the disclosed technology are not limited thereto. As shown in FIG. 4, the condensing pattern (ML) may be positioned continuously in the pixel areas (PA1 and PA2) and the non-pixel areas (NPA1 and NPA2), and the end of the convex lens shape may be formed to be positioned in the middle of the pixel areas PA1 and PA2, but embodiments of the disclosed technology are not limited thereto. For example, the condensing pattern (ML) may be discontinued in the non-pixel areas (NPA1 and NPA2). In this case, a plurality of condensing patterns (MLs) may be positioned in respective pixel areas (PA1 and PA2). In some embodiments, the condensing pattern (ML) may not be positioned in the second sub pixel (SP2).

The photodetector (SPAD) may be used as a photoelectric conversion device including a photosensitive P-N junction. In some implementations, the photodetector (SPAD) may detect a single photon (a single photon of L2) reflected from the target object (see the TO in FIG. 1) and may generate pixel data (or a current pulse, a pixel signal, a pulse signal) corresponding to the detected single photon. Herein, pixel data may be generated through a series of steps when avalanche breakdown is triggered by a single photon incident in a Geiger mode, in which a voltage between a cathode and an anode is higher than a breakdown voltage, that is, a reverse bias voltage is applied.

Referring to the enlarged view of FIG. 4, avalanche breakdown may occur in the intermediate area (MA) within the photodetector (SPAD). Holes (h+) may be placed in an area adjacent to the second semiconductor area (CD2) of the intermediate area (MA), and electrons (e−) may be placed in another area adjacent to the first semiconductor area (CD1) of the intermediate area (MA). The holes (h+) in the area and the electrons (e−) in the other area may be bonded to form electron (e−)-hole (h+) pairs (electron-hole pairs). The electron (e−)-hole (h+) pairs (electron-hole pairs) may be subjected to impact ionization due to photons of second light (L2).

Specifically, when the reverse bias voltage is applied to the photodetector (SPAD) to increase the electric field, the strongly applied electric field causes the electrons (e−) generated by incident photons to move, resulting in impact ionization, which generates electron (e−)-hole (h+) pairs (electron-hole pairs). Electrons (e−) and holes (h+) generated by the impact ionization phenomenon collide with each other and a large number of carriers may be generated.

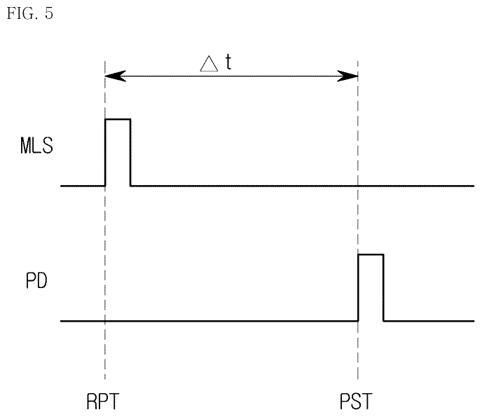

FIG. 5 is a diagram illustrating a direct ToF method of a pixel.

Referring to FIGS. 1 and 5, while the image sensing device 100 is active, the light source (LS) may emit first light (L1) (or emission light) to the target object (TO) by a reference pulse signal (MLS). A time point at which a pulse of the reference pulse signal (MLS) is generated may be defined as a reference pulse time point (RPT). The pixel array 110 and the readout circuit 150 may detect a pulse signal that is incident after reflected from the target object (TO) to generate pixel data (PD).

The image signal processor (ISP) 200 may process the pixel data (PD) input from the image sensing device 100, and may generate a depth image (in the form of a histogram) representing the distance to the target object (TO). When the direct ToF method is applied, the image signal processor 200 may calculate the distance to the target object (TO) for each pixel on the basis of the time delay represented by the pixel data (PD) received from the readout circuit 150. The image signal processor 200 may analyze the pixel data (PD) to determine the time point when the pixel data (PD) has a value of threshold data or greater, as a pulse detection time point (PST). The image signal processor 200 may calculate the time of flight (ToF, Δt) that is the time difference from the reference pulse time point (RPT) to the pulse detection time point (PST), and may calculate the distance between the target object (TO) and the image sensing device 100 by computing the calculated time of flight (Δt) and the velocity of light (for example, a value obtained by dividing Δt by 2 is multiplied by the velocity of light).

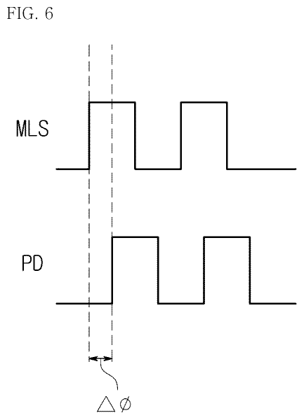

FIG. 6 is a diagram illustrating an indirect ToF method of a pixel.

Referring to FIGS. 1 and 6, while the image sensing device 100 is active, the light source (LS) may emit first light (L1) (or emission light) to the target object (TO) by a reference pulse signal (MLS). A time point at which a pulse of the reference pulse signal (MLS) is generated may be defined as a reference pulse time point (RPT). The pixel array 110 and the readout circuit 150 may detect a pulse signal that is incident after reflected from the target object (TO) to generate pixel data (PD).

The image signal processor 200 may process the pixel data (PD) input from the image sensing device 100, and may generate a depth image (in the form of a histogram) representing the distance to the target object (TO). When the indirect ToF method is applied, the image signal processor 200 may calculate the distance to the target object (TO) for each pixel on the basis of the phase delay (Δφ) represented by the pixel data (PD) received from the readout circuit 150.

An imaging system according to an embodiment may operate in the direct ToF method, but embodiments of the disclosed technology are not limited thereto. Hereinafter, for convenience of description, a description will be made focusing on the direct ToF method.

FIG. 7 is a diagram illustrating an imaging system according to an embodiment.

Referring to FIG. 7, an imaging system according to an embodiment may include a photodetector (SPAD), an analog quenching transistor (QX), a readout transistor (RT), a readout circuit 150, and an ISP 200. An anode electrode (AND) may be formed at one end of the photodetector (SPAD), and a cathode electrode (CAT) may be formed at the other end of the photodetector (SPAD). The anode electrode (AND) and the cathode electrode (CAT) have a relative concept, and their positions may be interchanged. For example, the anode electrode (AND) may be the second semiconductor area (CD2) of the photodetector (SPAD), and the cathode electrode (CAT) may be the first semiconductor area (CD1) of the photodetector (SPAD), but embodiments of the disclosed technology are not limited thereto. A diode voltage (VSPAD) may be applied to the anode electrode (AND) of the photodetector (SPAD). The cathode electrode (CAT) may be connected to a first node (N1). Second light (L2) is applied to the photodetector (SPAD) (see FIG. 3). The analog quenching transistor (QX) may be connected to the first node (N1). An analog quenching voltage (VDD) may be applied to a first electrode of the analog quenching transistor (QX), and a second electrode thereof may be connected to the first node (N1), and a quenching control signal (QCS) may be applied to a gate electrode of the analog quenching transistor (QX), and turning on/turning off of the analog quenching transistor (QX) may be controlled by the quenching control signal (QCS).

The readout transistor (RT) may be connected to the first node (N1). A first electrode of the readout transistor (RT) may be connected to the first node (N1), and a second electrode thereof may be connected to the readout circuit 150, and a readout control signal (RCS) may be applied to a gate electrode of the readout transistor (RT), and turning on/turning off of the readout transistor (RT) may be controlled by the readout control signal (RCS).

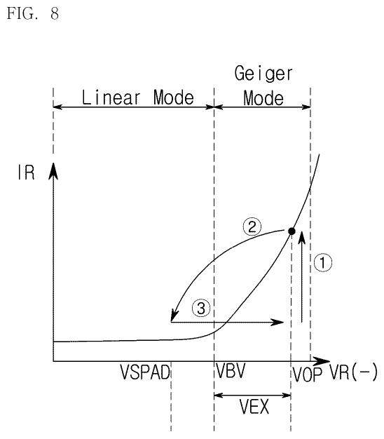

FIG. 8 is a diagram illustrating modes of a single-photon avalanche diode according to an embodiment. The horizontal axis in FIG. 8 represents the voltage (VR) applied to the single-photon avalanche diode (see the SPAD in FIG. 7), and the vertical axis represents the current (IR) output from the single-photon avalanche diode (see the SPAD in FIG. 7).

Referring to FIGS. 7 and 8, the modes of the single-photon avalanche diode may include a linear mode and a Geiger mode. The distinction between the linear mode and the Geiger mode is based on the breakdown voltage (VBV). When the voltage applied to the photodetector (SPAD) is equal to or greater than the breakdown voltage (VBV), the photodetector (SPAD) may operate in the Geiger mode. When the voltage applied to the photodetector (SPAD) is less than the breakdown voltage (VBV), the photodetector (SPAD) may operate in the linear mode. The voltage (VR) applied to the photodetector (SPAD) may be based on the (−) voltage. Therefore, in the embodiments of the disclosed technology, it is considered that the greater the (−) value, the greater the level of the voltage. However, embodiments of the disclosed technology are not limited thereto. In the linear mode and the Geiger mode, the diode voltage (VSPAD) may have a constant level. For example, the diode voltage (VSPAD) may be set to be a voltage lower than the breakdown voltage (VBV). When the diode voltage (VSPAD) is higher than the breakdown voltage (VBV), the photodetector (SPAD) may enter the Geiger mode even though the analog quenching transistor (QX) is not turned on. In this case, even though light (L2) is not applied, a large current (IR) may be generated from the photodetector (SPAD) due to random avalanche. Therefore, it is preferable that the diode voltage (VSPAD) is set to have a voltage lower than the breakdown voltage (VBV).

For a more specific description of the Geiger mode and the linear mode, each voltage level will be described as an example. The breakdown voltage (VBV) may be-20 V, and the diode voltage (VSPAD) may be −19 V. When the analog quenching transistor (QX) is turned off, the voltage applied to the photodetector (SPAD) is −19 V and is less than the breakdown voltage (VBV), so the photodetector (SPAD) operates in the linear mode. In the linear mode, even when light (L2) is incident to the photodetector (SPAD), the level of the current (IR) output from the photodetector (SPAD) may not be high and the level of the current (IR) may rise in proportion to the number of carriers (e− or h+) generated from impact ionization, but the number of carriers may not be large. Although the analog quenching transistor (QX) is turned on, when the analog quenching voltage (VDD) is less than 1 V, the voltage (VR) applied to the photodetector (SPAD) is −19V-(a voltage less than 1 V) and is less than the breakdown voltage (VBV), so the photodetector (SPAD) operates in the linear mode.

### Reset Operation

In reset operation (\textcircled{3}), when the analog quenching voltage (VDD) of 1 V is applied, the voltage (VR) applied to the photodetector (SPAD) becomes equal to the breakdown voltage (VBV). From this point on, the photodetector (SPAD) operates in the Geiger mode. In the Geiger mode, as the voltage (VR) applied to the photodetector (SPAD) increases, the level of the current (IR) output from the photodetector (SPAD) rises very steeply. However, in reset operation (\textcircled{3}), when the voltage (VR) applied to the photodetector (SPAD) is set to be equal to the breakdown voltage (VBV), the photodetector (SPAD) may operate in the linear mode rather than the Geiger mode due to some error. Therefore, in reset operation (\textcircled{3}), the voltage (VR) applied to the photodetector (SPAD) may be set upto the operating voltage (VOP). For example, the operating voltage (VOP) may be greater than the breakdown voltage (VBV), and is assumed to be −23 V, for example. That is, the operating voltage (VOP) greater than the breakdown voltage (VBV) is preset, and an operation to increase the voltage (VR) applied to the photodetector (SPAD) to the operating voltage (VOP) through the analog quenching voltage (VDD) is performed in reset operation (\textcircled{3}). To increase the voltage (VR) applied to the photodetector (SPAD) to the operating voltage (VOP) of −23 V, the analog quenching voltage (VDD) needs to be 4 V (−19V−4V=−23V). The voltage obtained by subtracting the breakdown voltage (VBV) from the operating voltage (VOP) may be a setting voltage (VEX), and in this case, may be −2 V.

### Avalanche Operation

In avalanche operation (\textcircled{1}), substantial impact ionization occurs in the photodetector (SPAD) and a large number of carriers are generated, so the level of the current (IR) output from the photodetector (SPAD) may be high. That is, the level of the output current (IR) is high, so the operation of generating a pulse signal that is incident after reflected from the target object (TO) described with reference to FIG. 4 may be performed in avalanche operation (\textcircled{1}) of the photodetector (SPAD). The pulse signal generated from the photodetector (SPAD) is provided to the readout circuit 150 when the readout transistor (RT) is turned on. The TDC 151 of the readout circuit 150 generates pixel data (PD) on the basis of the pulse signal generated and transmitted from the photodetector (SPAD), and the TDC buffer 153 stores the generated pixel data (PD).

### Quenching Operation

In quenching operation (\textcircled{2}), the analog quenching transistor (QX) may be turned off, and thus, the voltage (VR) applied to the photodetector (SPAD) may decrease back to the level of the diode voltage (VSPAD). The photodetector (SPAD) according to an embodiment repeats reset operation (\textcircled{3}), avalanche operation (\textcircled{1}), and quenching operation (\textcircled{2}).

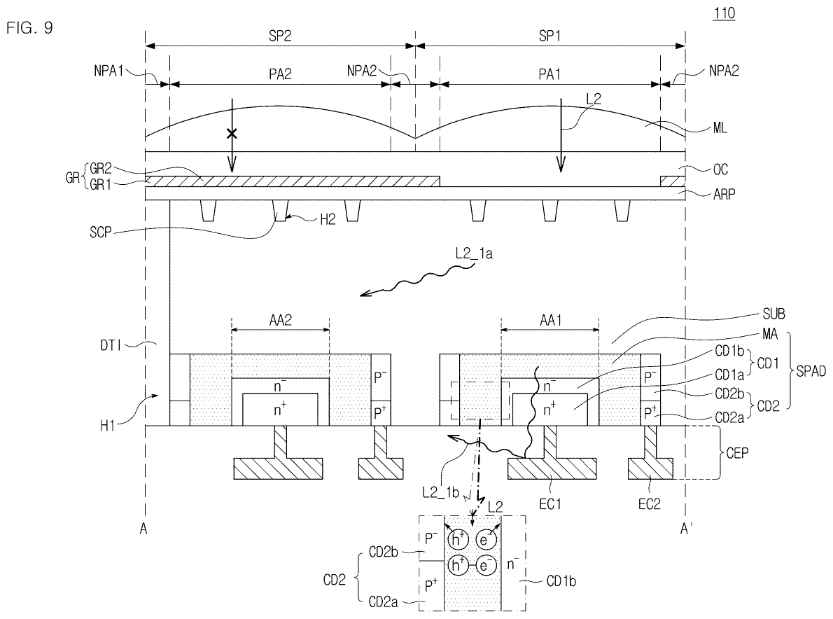

FIG. 9 is a schematic diagram illustrating that some of the light incident to the first sub pixel leaks to the second sub pixel.

Referring to FIG. 9, some (L2_1a and L2_1b) of the second light (L2) incident to the substrate (SUB) of the first sub pixel (SP1) may leak to the second sub pixel (SP2). As shown in FIG. 4, unlike the first non-pixel area (NPA1), the separation part may not be placed in the second non-pixel area (NPA2). Thus, the substrate (SUB) of the first sub pixel (SP1) and the substrate (SUB) of the second sub pixel (SP2) may be physically connected to each other and may not be discontinued. Therefore, some second light (L2_1a) of the second light (L2) incident to the first pixel area (PA1) may leak from the substrate (SUB) of the first sub pixel (SP1) to the substrate (SUB) of the second sub pixel (SP2). Further, some second light (L2_1b) of the second light (L2) incident to the substrate (SUB) of the first sub pixel (SP1) may be reflected from the electrodes (EC1 and EC2) below the photodetector (SPAD) of the first sub pixel (SP1), and may be incident to the photodetector (SPAD) of the second sub pixel (SP2). That is, as the grid part (GR) is placed in the second sub pixel (SP2), the second light (L2) may not be directly received, but the second light (L2_1a and L2_1b) leaked from the first sub pixel (SP1) may be received.

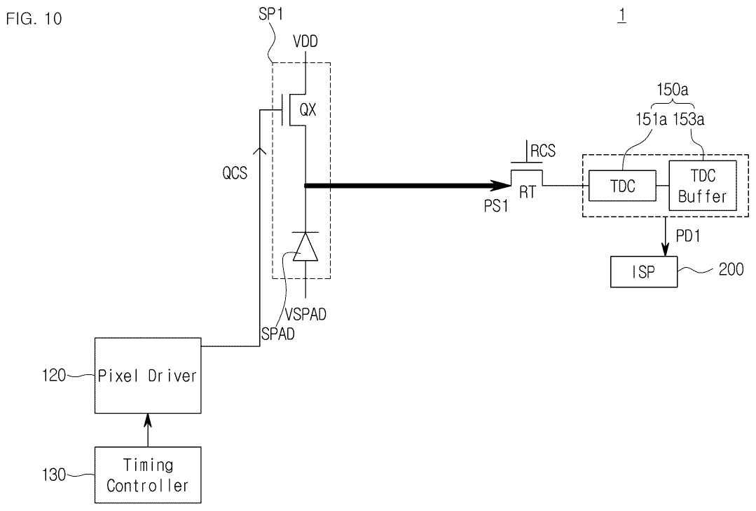

FIG. 10 is a diagram illustrating conversion of a first pulse signal generated by the first sub pixel to first pixel data.

Referring to FIG. 10, an imaging system 1 according to an embodiment may include a first sub pixel (SP1). A pixel driver 120 may apply a quenching control signal (QCS) to a gate electrode of an analog quenching transistor (QX) of the first sub pixel (SP1) to control turning on/turning off of the analog quenching transistor (QX) of the first sub pixel (SP1).

The first sub pixel (SP1) may generate a first pulse signal (PS1) and transmit the same to a readout transistor (RT), and turning on/turning off of the readout transistor (RT) may be controlled by a readout control signal (RCS). The first pulse signal (PS1) is transmitted to a first readout circuit 150a through the readout transistor (RT). A first TDC 151a of the first readout circuit 150a receives the first pulse signal (PS1), and generates first pixel data (PD1). A first TDC buffer 153a stores the first pixel data (PD1) received from the first TDC 151a, and transmits the same to an ISP 200.

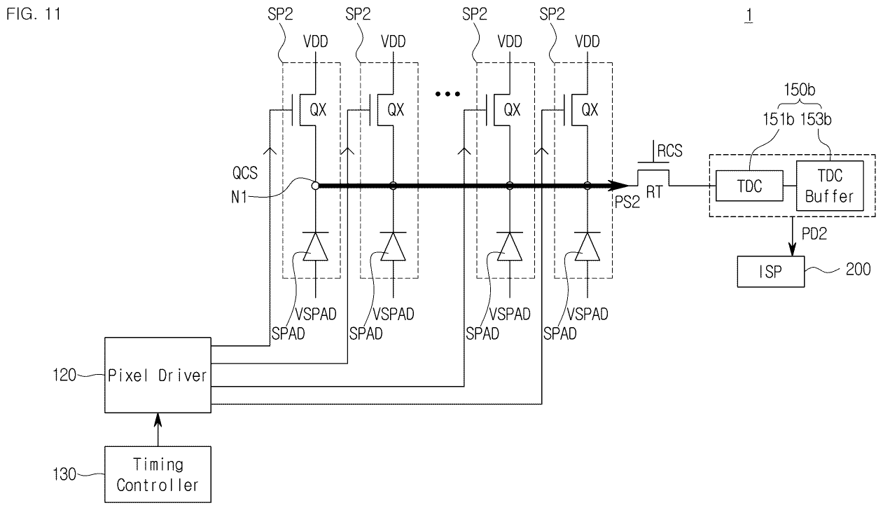

FIG. 11 is a diagram illustrating conversion of a second pulse signal generated by second sub pixels to second pixel data.

Referring to FIG. 11, an imaging system 1 according to an embodiment may include second sub pixels (SP2s). A pixel driver 120 may apply a quenching control signal (QCS) to a gate electrode of an analog quenching transistor (QX) of each of the second sub pixels (SP2s) to control turning on/turning off of the analog quenching transistors (QXs) of the second sub pixels (SP2s). The analog quenching transistors (QXs) of the second sub pixels (SP2s) may be simultaneously turned on.

The second sub pixels (SP2s) generate respective pulse signals and transmit the same to a readout transistor (RT). The second sub pixels (SP2s) are connected to each other via a first node (N1), so the pulse signals generated by the second sub pixels (SP2s) may be synthesized (hereinafter, a pulse signal resulting from synthesis is referred to as a second pulse signal (PS2)). Turning on/turning off of the readout transistor (RT) may be controlled by a readout control signal (RCS). The second pulse signal (PS2) is transmitted to a second readout circuit 150b through the readout transistor (RT). A second TDC 151b of the second readout circuit 150b receives the second pulse signal (PS2), and generates second pixel data (PD2). A second TDC buffer 153b stores the second pixel data (PD2) received from the second TDC 151b, and transmits the same to an ISP 200.

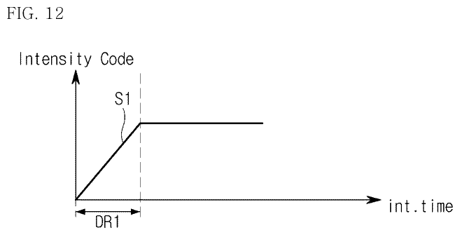

FIG. 12 is a graph illustrating intensity code over light emission time of an imaging system according to a comparative example. FIG. 12 illustrates pixel data generated on the basis of a pulse signal generated by a pixel according to the comparative example. Unlike the pixel (SP: SP1 and SP2) shown in FIG. 2, the pixel according to the comparative example may include only one first sub pixel (SP1). When the pixel includes only one first sub pixel (SP1), the area of the one first sub pixel (SP1) of the pixel may be substantially the same as the sum of the areas of the first sub pixel (SP1) and the second sub pixels (SP2s) shown in FIG. 2. In FIG. 12, the pixel data is represented as the intensity code. In FIG. 12, the horizontal axis depicts the light emission time (int.time), and the vertical axis depicts the intensity code.

Referring to FIG. 12, according to the imaging system of the comparative example, the intensity code increases to have a first slope (S1) up to a first dynamic range (DR1), and the intensity code is saturated at the light emission time above the first dynamic range (DR1).

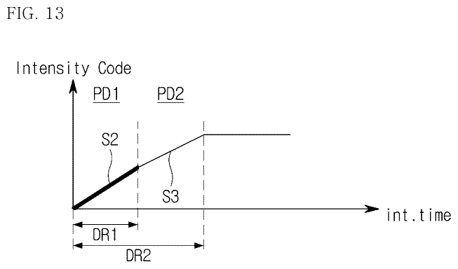

FIG. 13 is a graph illustrating intensity code over light emission time of an imaging system according to an embodiment. FIG. 13 illustrates pixel data (PD1 and PD2) generated on the basis of a pulse signal generated by a pixel (an SP in FIG. 2) according to an embodiment.

Referring to FIG. 13, according to an imaging system according to an embodiment, the intensity code increases (generated on the basis of first pixel data (PD1)) to have a second slope (S2) up to a first dynamic range (DR1), and the intensity code increases (second pixel data (PD2)) to have a third slope (S3) above the first dynamic range (DR1), and the intensity code is saturated at the light emission time above a second dynamic range (DR2). The second slope (S2) may be smaller than the first slope (S1) in FIG. 12. As shown in FIG. 9, according to an embodiment, some (L2_1a and L2_1b) of the second light (L2) incident to the substrate (SUB) of the first sub pixel (SP1) is induced to leak to the second sub pixel (SP2), thereby generating the second pixel data (PD2). The ISP (see 200 in FIGS. 10 and 11) may add the output (the first pixel data (PD1) having the first dynamic range (DR1)) of the first sub pixel (SP1) to the output (the second pixel data (PD2)) of the second sub pixel (SP2). Thus, summed pixel data having the second dynamic range (DR2) may be generated.

As in the above-described comparative example, when the pixel includes only the first sub pixel (SP1) having the first pixel area (PA1) exposed by the grid part (GR), the first TDC buffer may be saturated by the photodetector (SPAD) of the first sub pixel (SP1). As illustrated in the enlarged view of FIG. 4, the photodetector (SPAD) may be or include a single-photon avalanche diode, and avalanche breakdown is triggered by a single photon, so the single-photon avalanche diode may generate a large number of pulse signals. In particular, in the case of high illumination or a short distance to the target object, the first pixel data exceeding the capacity of the first TDC buffer may be generated.

However, according to an embodiment, one pixel (SP) includes a first sub pixel (SP1) and second sub pixels (SP2s) receiving second light that leaks from the first sub pixel (SP1), so that the first sub pixel (SP1) is prevented from generating the first pixel data exceeding the capacity of the first TDC buffer, and this is applicable for high illumination or short distances.

In addition, as described above, the ISP (see 200 in FIGS. 10 and 11) may add the output (the first pixel data (PD1) having the first dynamic range (DR1)) of the first sub pixel (SP1) to the output (the second pixel data (PD2)) of the second sub pixel (SP2). Thus, summed pixel data having the second dynamic range (DR2) may be generated, thereby improving the dynamic range of the imaging system.

In addition, according to the direct ToF method, the distance to the target object needs to be measured several times for reliability. However, according to an embodiment, one pixel (SP) includes a first sub pixel (SP1) and second sub pixels (SP2s) receiving second light that leaks from the first sub pixel (SP1), to generate the pixel data (PD1 and PD2), so that the time exposed to light and the operating time of the photodetector (SPAD) are reduced to minimize power consumption and maximize the efficiency of the light source.

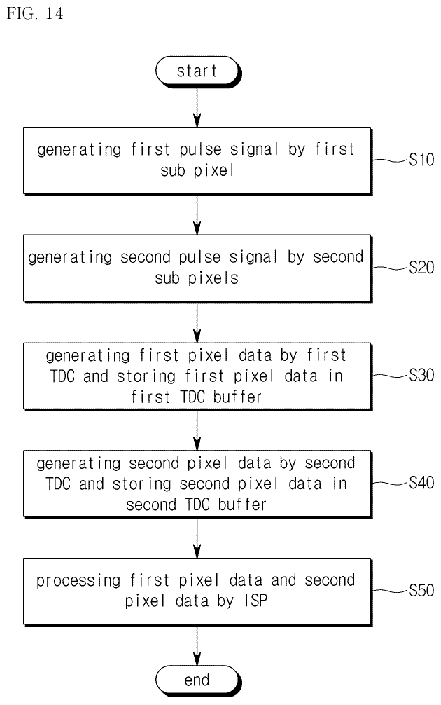

Hereinafter, a method of operating the imaging system 1 described with reference to FIGS. 1 to 13 will be described. In describing FIG. 14, a redundant description of the parts and the configurations described above with reference to FIGS. 1 to 13 will be omitted.

FIG. 14 is a flowchart illustrating a method of operating an imaging system according to an embodiment.

Referring to FIGS. 10 and 14, a method of operating an imaging system according to an embodiment includes generating a first pulse signal (PS1) by a first sub pixel (SP1) in step S10.

Next, referring to FIGS. 11 and 14, a method of operating an imaging system according to an embodiment includes generating a second pulse signal (PS2) by second sub pixels (SP2s) in step S20.

Next, referring to FIGS. 10 and 14, a method of operating an imaging system according to an embodiment includes generating first pixel data (PD1) by a first TDC 151a, and storing the first pixel data (PD1) by a first TDC buffer 153a in step S30.

Next, referring to FIGS. 11 and 14, a method of operating an imaging system according to an embodiment includes generating second pixel data (PD2) by a second TDC 151b, and storing the second pixel data (PD2) by a second TDC buffer 153b in step S40.

In FIG. 14, after the second sub pixel (SP2) generates the second pulse signal (PS2), a method of operating an imaging system according to an embodiment illustrates that the first TDC 151a generates the first pixel data (PD1), and the first TDC buffer 153a stores the first pixel data (PD1). However, embodiments of the disclosed technology are not limited thereto, and the first TDC 151a may generate first pixel data (PD1), the first TDC buffer 153a may store the first pixel data (PD1), and then the second sub pixel (SP2) may generate a second pulse signal (PS2). After the first TDC 151a generates the first pixel data (PD1) and the first TDC buffer 153a stores the first pixel data (PD1), the second sub pixel (SP2) is able to generate the second pulse signal (PS2) because the first and the second readout circuit 150a and 150b shown in FIGS. 10 and 11 are distinct from each other and the readout transistor (RT) connected to the first sub pixel (SP1) and the readout transistor (RT) connected to the second sub pixel (SP2) are different transistors.

Next, referring to FIGS. 10, 11, and 14, the ISP 200 performs image processing (or summation processing) on the generated first pixel data (PD1) and the generated second pixel data (PD2) in step S50. The summed pixel data (or image) generated by the ISP 200 may be in the form of an improved dynamic range (DR1→DR2) as shown in FIG. 13.

Hereinafter, other embodiments of an imaging system 1 according to an embodiment will be described. In describing the following embodiments, a redundant description of the parts or the configurations described above with reference to FIGS. 1 to 13 will be omitted.

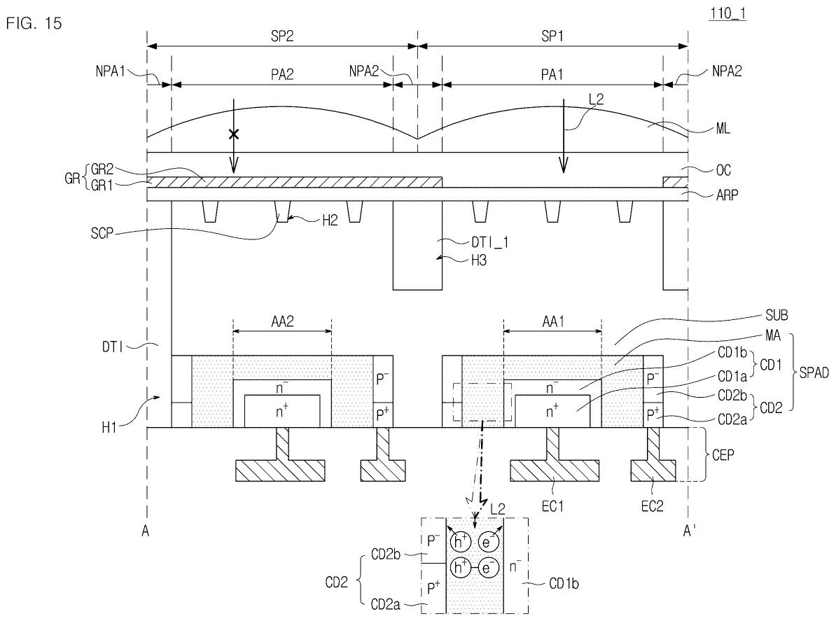

FIG. 15 is a cross-sectional view of a pixel array based on some implementations of the disclosed technology.

Referring to FIG. 15, unlike the pixel array 110 as shown in FIG. 4, a pixel array 110_1 according to the present embodiment has a third groove (H3) formed in the second non-pixel area (NPA2).

In some implementations, the third groove (H3) may partially recess the substrate (SUB). The depth of the third groove (H3) may be smaller than the depth of the first groove (H1), and may be greater than the depth of the second groove (H2). A second separation part (e.g., the deep trench isolation (DTI_1) element) may be placed in the third groove (H3). The second separation part may be configured to separate the first pixel area (PA1) in the first sub-pixel (SP1) from the second pixel area(PA2) in the second sub-pixel (SP2) adjacent to the first sub-pixel (SP1). The depth (or thickness) of the second separation part (e.g., DTI_1) may be smaller than the depth (or thickness) of the separation part (DTI).

The remaining structures in the example of FIG. 4 are similar to those described above with reference to FIG. 4, and thus, a detailed description thereof will be omitted.

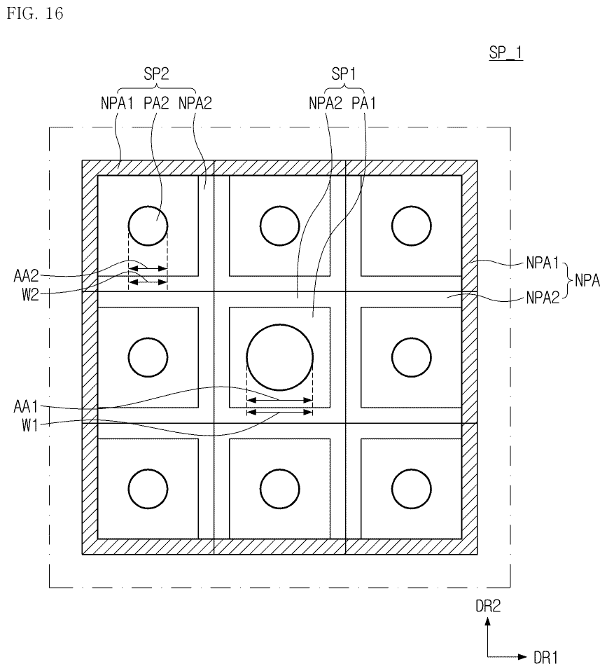

FIG. 16 is a plan view of a pixel based on some implementations of the disclosed technology. In the below, the differences are mainly discussed as compared to the embodiments as described above.

Referring to FIG. 16, unlike the pixel (SP) as shown in FIG. 3, the area (or a second width (W2)) of a second active area (AA2) of a second sub pixel (SP2) of a pixel (SP_1) according to the present embodiment is smaller than the area (or a first width (W1)) of the first active area (AA1) of the first sub pixel (SP1).

As described above, since the first sub pixel (SP1) generates the first pulse signal by mainly receiving second light (L2) and the second sub pixel (SP2) generates the second pulse signal based on light that leaks from the first sub pixel (SP1), the area (or width) of the first active area (AA1) of the first sub pixel (SP1) is set to be greater than the area (or width) of the second active area (AA2) of the second sub pixel (SP2), thereby increasing the amount of light first received by the first sub pixel (SP1).

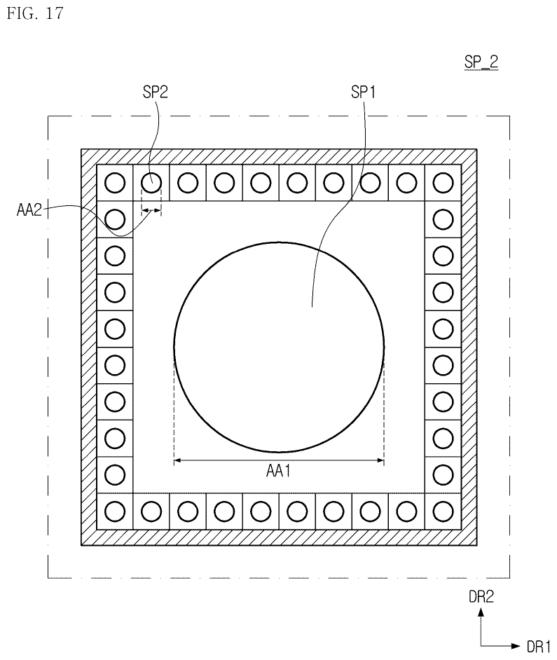

FIG. 17 is an example of a plan view of a pixel based on some implementations of the disclosed technology. In the below, the differences are mainly discussed as compared to the embodiments as described above.

Referring to FIG. 17, unlike the pixel (SP) as shown in FIG. 3, a first sub pixel (SP1) and second sub pixels (SP2s) of a pixel (SP_2) according to the present embodiment have different pitches.

In some implementations, the first active area (AA1) of the first sub pixel (SP1) and the second active area (AA2) of the second sub pixel (SP2) may have a particular first separation distance, and the adjacent second sub pixels (SP2s) may have a particular second separation distance. The first separation distance may vary depending on the arrangement area of the second sub pixels (SP2s), as long as the first separation distance is greater than the second separation distance.

According to the present embodiment, the second separation distance of the adjacent second sub pixels (SP2s) is designed to be smaller than the first separation distance, so that the sufficient area of the first active area (AA1) of the first sub pixel (SP1) is ensured, thereby improving the efficiency of light reception.

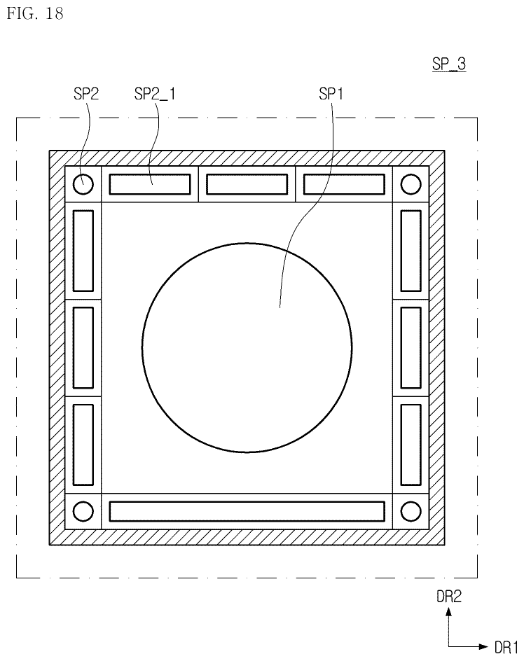

FIG. 18 is an example of a plan view of a pixel based on some implementations of the disclosed technology. In the below, the differences are mainly discussed as compared to the embodiments as described above.

Referring to FIG. 18, unlike the pixel (SP_2) shown in FIG. 18, second sub pixels of a pixel (SP_3) according to the present embodiment have different areas or shapes.

In some implementations, the second sub pixels (SP2 and SP2_1) may include 2-1 sub pixels (SP2s) positioned at the corner areas of the pixel (SP_3), and 2-2 sub pixels (SP2_1s) positioned at the area corresponding to each edge. The area of the 2-1 sub pixel (SP2) (or the area of the active area of the 2-1 sub pixel (SP2)) may be smaller than the area of the 2-2 sub pixel (SP2_1) (or the area of the active area of the 2-2 sub pixel (SP2_1)). The shape of the 2-1 sub pixel (SP2) (or the shape of the active area of the 2-1 sub pixel (SP2)) may be circular, but is not limited thereto. The shape of the 2-2 sub pixel (SP2_1) (or the shape of the active area of the 2-2 sub pixel (SP2_1)) may be circular, but is not limited thereto.

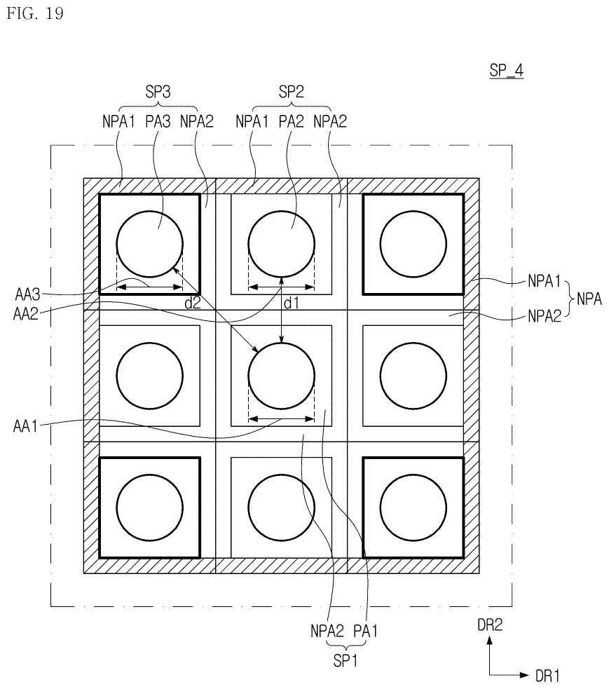

FIG. 19 is a plan view of a pixel based on some implementations of the disclosed technology. In the below, the differences are mainly discussed as compared to the embodiments as described above.

Referring to FIG. 19, unlike the pixel (SP) shown in FIG. 3, a pixel (SP_4) according to the present embodiment further includes a third sub pixel (SP3).

In some implementations, with the first sub pixel (SP1) in the center, the second and the third sub pixels (SP2s and SP3s) may surround the first sub pixel (SP1). For example, the second sub pixels (SP2s) may be positioned above, below, to the left, and to the right of the first sub pixel (SP1), and the third sub pixels (SP3s) may be positioned diagonally to the first sub pixel (SP1). For example, a separation distance (d1) between the second active area (AA2) of the second sub pixel (SP2) and the first active area (AA1) of the first sub pixel (SP1) may be smaller than a separation distance (d2) between the third active area (AA3) of the third sub pixel (SP3) and the first active area (AA1) of the first sub pixel (SP1). The structure of the second sub pixel (SP2) may be the same as the structure of the third sub pixel (SP3). The second sub pixel (SP2) and the third sub pixel (SP3) may be distinguished in terms of their operations.

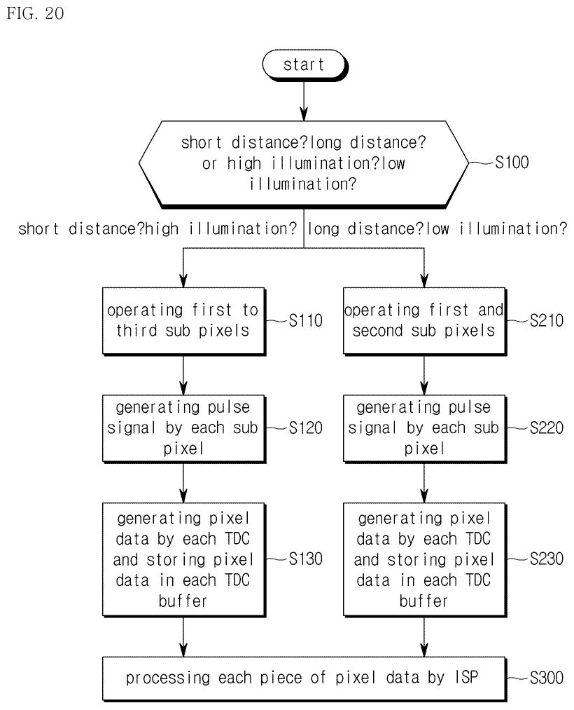

FIG. 20 is an example flowchart illustrating a method of operating an imaging system based on some implementations of the disclosed technology. FIG. 20 shows a method of operating an imaging system including the pixel (SP_4) shown in FIG. 19.

Referring to FIGS. 19 and 20, a method of operating an imaging system according to the present embodiment may include determining whether the distance to the target object is a short distance or a long distance, or determining whether illumination is high illumination or low illumination in step S100. When determining whether the distance to target object is the short distance or the long distance, whether the distance to the target object is the short distance or the long distance may be determined on the basis of the first pulse signal generated from the first sub pixel (SP1) in FIG. 19 and the first pixel data resulting from conversion of the first pulse signal. However, embodiments of the disclosed technology are not limited thereto, and all of the pulse signals generated from the first to the third sub pixel (SP1 to SP3) may be used. When determining whether illumination is high or low illumination, determination may be made using the light sensor 300 in FIG. 1, but embodiments of the disclosed technology are not limited thereto.

Next, in the case of a short distance or high illumination, the method of operating the imaging system according to the present embodiment may include operating the first to the third sub pixel (SP1 to SP3) in step S110.

Next, the method of operating the imaging system according to the present embodiment includes generating pulse signals by the first to the third sub pixel (SP1 to SP3) in step S120. For example, the first sub pixel (SP1) may generate the first pulse signal, the second sub pixel (SP2) may generate the second pulse signal, and the third sub pixel (SP3) may generate the third pulse signal. For example, the first pulse signal may be the largest, and the second pulse signal may be larger than the third pulse signal.

Next, in the method of operating the imaging system according to the present embodiment, respective TDC generate pieces of pixel data on the basis of the first to the third pulse signal, and respective TDC buffers store the generated pieces of pixel data. For example, the second sub pixels may share the same TDCs, and the third sub pixels may share the same TDCs, and the TDC of the second sub pixel and the TDC of the third sub pixel may be different from each other.

Next, in the method of operating the imaging system according to the present embodiment, the ISP processes each of the pieces of pixel data in step S300. The ISP performs image processing (or summation processing) on the generated first pixel data or the generated third pixel data. As shown in FIG. 13, the ISP may add the output (first pixel data having a first dynamic range) of the first sub pixel (SP1) and the output (second pixel data) of the second sub pixel (SP2), and may add the output (second pixel data) of the second sub pixel (SP2) and the output (third pixel data) of the third sub pixel (SP3) to generate summed pixel data having a third dynamic range greater than a second dynamic range.

In the case of a long distance or low illumination, the method of operating the imaging system according to the present embodiment may include operating the first and the second sub pixel (SP1 and SP2) in step S210.

Next, the method of operating the imaging system according to the present embodiment includes generating pulse signals by the first and the second sub pixel (SP1 and SP2) in step S220.

Next, in the method of operating the imaging system according to the present embodiment, respective TDCs generate pieces of pixel data on the basis of the first and the second pulse signal, and respective TDC buffers store the generated pieces of pixel data. For example, the second sub pixels may share the same TDCs.

Next, in the method of operating the imaging system according to the present embodiment, the ISP processes each of the pieces of pixel data in step S300. The ISP performs image processing (or summation processing) on the generated first pixel data and the generated second pixel data.

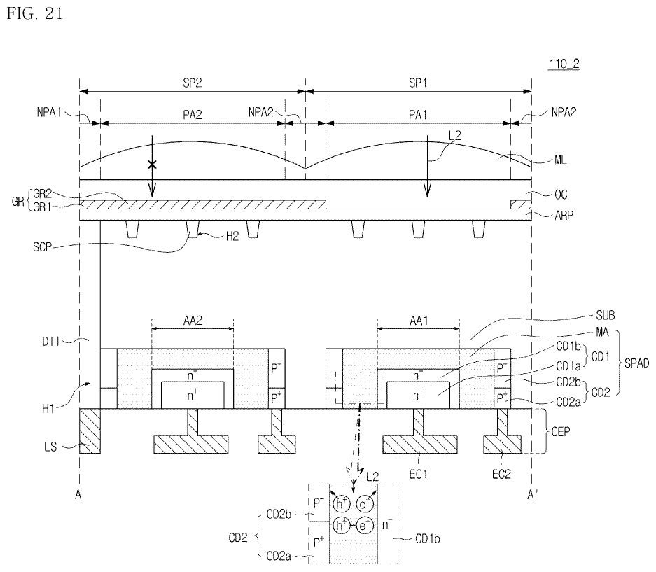

FIG. 21 is a cross-sectional view of a pixel array according to another embodiment.

Referring to FIG. 21, a circuit (CEP) of a pixel array 110_2 according to the present embodiment further includes a light shielding part (LS), and is different from the pixel array 110 shown in FIG. 3.

The light shielding part (LS) may be placed in the first non-pixel area (NPA1). As shown in FIG. 3, the first sub pixel (SP1) and the second sub pixel (SP2) may constitute one group pixel, and the light shielding part (LS) may prevent light incident on one group pixel from leaking to another adjacent group pixel. The light shielding part (LS) may be formed by the same process as the other electrodes (EC1 and EC2) of the circuit (CEP), but embodiments of the disclosed technology are not limited thereto.

An image sensing device, an imaging system, and a method of operating the imaging system according to various embodiments of the disclosed technology may be described as follows.

In one aspect, an image sensing device is provided to comprise: a substrate; and a plurality of pixels supported by the substrate, wherein the plurality of pixels includes a first pixel that includes: a first sub pixel included in a pixel of the plurality of pixels and including a first pixel area, and a portion of a second non-pixel area adjacent to the first pixel area; a plurality of second sub pixels disposed around the first sub pixel, each of the plurality of second sub pixels including a second pixel area, another portion of the second non-pixel area adjacent to the second pixel area, and a first non-pixel area between the second pixel area and a second pixel adjacent to the first pixel; photoelectric conversion elements respectively placed in the first sub pixel and the plurality of second sub pixels and configured to detect a photon reflected from a target object and generate a pixel signal corresponding to the detected photon; a grid structure disposed above the substrate and including a first grid placed in the first non-pixel area and the second non-pixel area, and a second grid placed in the second pixel area, and wherein the substrate includes a first recess in the first non-pixel area and the substrate includes a second recess in the second non-pixel area, and a depth of the first recess is greater than a depth of the second recess.

In some implementations, the first recess includes a first separation element configured to separate the first pixel from the second pixel.

In some implementations, in the first non-pixel area, the substrate is fully penetrated to allow the first separation element to have surfaces contacting surfaces of the substrate.

In some implementations, the second recess includes a second separation element configured to separate the first pixel area from the second pixel area, and a thickness of the first separation element is greater than a thickness of the second separation element.

In some implementations, the grid structure includes metal.

In some implementations, each of the photoelectric conversion elements includes a single-photon avalanche diode.

In some implementations, an area of an active area of the first pixel area is larger than an area of an active area of the second pixel area.

In some implementations, a separation distance between an active area of the first pixel area and an active area of the second pixel area is greater than a separation distance between active areas of the second pixel areas.

In some implementations, the plurality of second sub pixels includes analog quenching transistors that are configured to turn on simultaneously.

In some implementations, each of the photoelectric conversion elements includes a first semiconductor area, a second semiconductor area, and an intermediate area between the first semiconductor area and the second semiconductor area.

In some implementations, the image sensing device further comprises a circuit disposed below the substrate and further including a first electrode connected to the first semiconductor area, and a second electrode connected to the second semiconductor area, wherein the first electrode is connected to an analog quenching transistor, and a diode voltage is applied to the second electrode.

In some implementations, the circuit further includes a light shielding element overlapping the first non-pixel area.

In another aspect, an imaging system is provided to comprise: an image sensing device including: a pixel array including a plurality of pixels, each including a first sub pixel configured to generate a first pulse signal and a plurality of second sub pixels positioned around the first sub pixel and configured to generate a second pulse signal; a first readout circuit configured to generate and store first pixel data based on the first pulse signal generated from the first sub pixel; and a second readout circuit configured to generate and store second pixel data based on the second pulse signal generated from the plurality of second sub pixels; and an image sensing processor configured to process the first pixel data and perform a summation processing on the second pixel data.

In some implementations, the plurality of second sub pixels shares the second readout circuit.

In some implementations, the pixel array further includes a circuit, a substrate on the circuit, and a grid structure above the substrate, and the first sub pixel includes a first pixel area, and a second non-pixel area between the first pixel area and the plurality of second sub pixels, and each of the plurality of second sub pixels includes a second pixel area, the second non-pixel area between the second pixel area and the second sub pixels adjacent to the second pixel area, and a first non-pixel area between the second pixel area and another pixel adjacent to the second pixel area, and the grid structure includes a first grid placed in the first non-pixel area and the second non-pixel area, and a second grid placed in the second pixel area.

In some implementations, a recess depth of the substrate in the first non-pixel area is greater than a recess depth of the substrate in the second non-pixel area.

In another aspect, a method of operating an imaging system is provided. The method comprises: generating a first pulse signal by a first photoelectric conversion element of a first sub pixel included in a pixel of the imaging system; generating a second pulse signal by second photoelectric conversion elements of a plurality of second sub pixels disposed around the first sub pixel; generating, by a first readout circuit in the imaging system, first pixel data based on the first pulse signal by a first readout circuit; generating, by a second readout circuit in the imaging system, second pixel data based on the second pulse signal; processing, by an image signal processor (ISP) in the imaging system, the first pixel data; and performing, by the ISP in the imaging system, a summation processing on the second pixel data.

In some implementations, the plurality of second sub pixels shares the second readout circuit.

In some implementations, the method further comprises: before the generating of the first pulse signal, determining whether a distance to a target object is a short distance or a long distance, or whether illumination is high illumination or low illumination, wherein the imaging system further includes third sub pixels positioned around the first sub pixel, each of the third sub pixels including an active area that is positioned further away from an active area of the first sub pixel than active areas of the plurality of second sub pixels are, and in response to the distance to the target object being the short distance or the illumination being the high illumination, the first sub pixel to the third sub pixels are operated.

In some implementations, in response to the distance to the target object being the long distance or the illumination being the low illumination, the first sub pixel and the plurality of second sub pixels are operated without operating the third sub pixels.

Although an embodiment of the present disclosure has been described above with reference to the accompanying drawings, those skilled in the art will understand that the above-described embodiments are examples of implementation of the disclosed technology. Variations and enhancements of the disclosed embodiments and other embodiments may be made based on what is disclosed and/or illustrated in this patent document.

I/We claim:

1. An image sensing device, comprising:
a substrate; and
a plurality of pixels supported by the substrate,
wherein the plurality of pixels includes a first pixel that includes:
a first sub pixel included in a pixel of the plurality of pixels and including a first pixel area, and a portion of a second non-pixel area adjacent to the first pixel area;
a plurality of second sub pixels disposed around the first sub pixel, each of the plurality of second sub pixels including a second pixel area, another portion of the second non-pixel area adjacent to the second pixel area, and a first non-pixel area between the second pixel area and a second pixel adjacent to the first pixel;
photoelectric conversion elements respectively placed in the first sub pixel and the plurality of second sub pixels and configured to detect a photon reflected from a target object and generate a pixel signal corresponding to the detected photon;
a grid structure disposed above the substrate and including a first grid placed in the first non-pixel area and the second non-pixel area, and a second grid placed in the second pixel area, and
wherein the substrate includes a first recess in the first non-pixel area and the substrate includes a second recess in the second non-pixel area, and a depth of the first recess is greater than a depth of the second recess.

2. The image sensing device of claim 1, wherein the first recess includes a first separation element configured to separate the first pixel from the second pixel.

3. The image sensing device of claim 2, wherein in the first non-pixel area, the substrate is fully penetrated to allow the first separation element to have surfaces contacting surfaces of the substrate.

4. The image sensing device of claim 2, wherein the second recess includes a second separation element configured to separate the first pixel area from the second pixel area, and a thickness of the first separation element is greater than a thickness of the second separation element.

5. The image sensing device of claim 1, wherein the grid structure includes metal.

6. The image sensing device of claim 1, wherein each of the photoelectric conversion elements includes a single-photon avalanche diode.

7. The image sensing device of claim 1, wherein an area of an active area of the first pixel area is larger than an area of an active area of the second pixel area.

8. The image sensing device of claim 1, wherein a separation distance between an active area of the first pixel area and an active area of the second pixel area is greater than a separation distance between active areas of second pixel areas.

9. The image sensing device of claim 1, wherein the plurality of second sub pixels includes analog quenching transistors that are configured to turn on simultaneously.

10. The image sensing device of claim 1, wherein each of the photoelectric conversion elements includes a first semiconductor area, a second semiconductor area, and an intermediate area between the first semiconductor area and the second semiconductor area.

11. The image sensing device of claim 10, further comprising a circuit disposed below the substrate and further including a first electrode connected to the first semiconductor area, and a second electrode connected to the second semiconductor area, wherein the first electrode is connected to an analog quenching transistor, and a diode voltage is applied to the second electrode.

12. The image sensing device of claim 11, wherein the circuit further includes a light shielding element overlapping the first non-pixel area.

13. An imaging system, comprising:
an image sensing device including:
a pixel array including a plurality of pixels, each including a first sub pixel configured to generate a first pulse signal and a plurality of second sub pixels positioned around the first sub pixel and configured to generate a second pulse signal;
a first readout circuit configured to generate and store first pixel data based on the first pulse signal generated from the first sub pixel;
and a second readout circuit configured to generate and store second pixel data based on the second pulse signal generated from the plurality of second sub pixels; and
an image sensing processor configured to process the first pixel data and perform a summation processing on the second pixel data.

14. The imaging system of claim 13, wherein the plurality of second sub pixels shares the second readout circuit.

15. The imaging system of claim 13, wherein the pixel array further includes a
circuit, a substrate on the circuit, and a grid structure above the substrate, and
the first sub pixel includes a first pixel area, and a second non-pixel area between the first pixel area and the plurality of second sub pixels, and
each of the plurality of second sub pixels includes a second pixel area, the second non-pixel area between the second pixel area and the plurality of second sub pixels adjacent to the second pixel area, and a first non-pixel area between the second pixel area and another pixel adjacent to the second pixel area, and
the grid structure includes a first grid placed in the first non-pixel area and the second non-pixel area, and a second grid placed in the second pixel area.

16. The imaging system of claim 15, wherein a recess depth of the substrate in the first non-pixel area is greater than a recess depth of the substrate in the second non-pixel area.

17. A method of operating an imaging system, the method comprising:
generating a first pulse signal by a first photoelectric conversion element of a first sub pixel included in a pixel of the imaging system;
generating a second pulse signal by second photoelectric conversion elements of a plurality of second sub pixels disposed around the first sub pixel;
generating, by a first readout circuit in the imaging system, first pixel data based on the first pulse signal by a first readout circuit;
generating, by a second readout circuit in the imaging system, second pixel data based on the second pulse signal;
processing, by an image signal processor (ISP) in the imaging system, the first pixel data; and
performing, by the ISP in the imaging system, a summation processing on the second pixel data.

18. The method of claim 17, wherein the plurality of second sub pixels shares the second readout circuit.

19. The method of claim 17, further comprising
before the generating of the first pulse signal, determining whether a distance to a target object is a short distance or a long distance, or whether illumination is high illumination or low illumination,
wherein the imaging system further includes third sub pixels positioned around the first sub pixel, each of the third sub pixels including an active area that is positioned further away from an active area of the first sub pixel than active areas of the plurality of second sub pixels are, and
in response to the distance to the target object being the short distance or the illumination being the high illumination, the first sub pixel to the third sub pixels are operated.

20. The method of claim 19, wherein in response to the distance to the target object being the long distance or the illumination being the low illumination, the first sub pixel and the plurality of second sub pixels are operated without operating the third sub pixels.
